(19) United States
(12) Patent Application Publication
(10) Pub. No.: US 2026/0036180 A1
(43) Pub. Date: Feb. 5, 2026

(54) MONOLITHIC SPRING ASSEMBLIES FOR HIGH-FREQUENCY PRESS-PACK MODULES

(71) Applicant: NUtech Ventures, Lincoln, NE (US)

(72) Inventors: Jun Wang, Lincoln, NE (US); Ekaterina Muravleva, Lincoln, NE (US); Bogac Canbaz, Lincoln, NE (US); Liyan Qu, Lincoln, NE (US)

(21) Appl. No.: 19/350,891

(22) Filed: Oct. 6, 2025

Related U.S. Application Data
(63) Continuation of application No. PCT/US2024/025139, filed on Apr. 18, 2024.
(60) Provisional application No. 63/496,759, filed on Apr. 18, 2023.

(51) Int. Cl. F16F 1/02; H01L 23/02

(52) U.S. Cl. CPC F16F 1/025; H01L 23/02; F16F 2224/0208

(57) ABSTRACT

A spring for use in a semiconductor device is provided, which includes a body having a plurality of slits to allow the body to deflect along a first direction; and one or more legs at one or both ends of the body. The plurality of slits are located in a plurality of planes perpendicular to the first direction and distributed along the first direction. The slits in a particular plane of the plurality of planes are interleaved with the slits in an adjacent plane of the plurality of planes

### CROSS REFERENCE TO RELATED APPLICATION

This Patent Application is a continuation of International Application No. PCT/US2024/025139, filed Apr. 18, 2024, which claims priority to U.S. Provisional Patent Application No. 63/496,759, entitled “MONOLITHIC SPRING FOR HIGH-FREQUENCY PRESS-PACK MODULES” filed Apr. 18, 2023, which are both incorporated herein by reference in their entireties.

### FIELD

The present disclosure relates to circuit protection technologies, and more specifically to monolithic spring (MS) devices useful in power protection modules.

### BACKGROUND

Emerging medium-voltage (MV) distribution-grid-scale power converters are seeking high-current, low-conduction-loss, and high-switching-speed power modules for higher distribution efficiency and reinforced grid resilience. Meanwhile, short-circuit failure modes (SCFM) are also necessary for series redundancy when the converter voltage is scaled up. Power modules with similar features for the conventional distribution grid are silicon (Si) press-pack (PP) SCRs (where SCR stands for silicon controlled rectifier), integrated gate-commutated thyristors (IGCTs), and insulated-gate bipolar transistors (IGBTs). However, these power modules are subjected to inevitable forward voltage drop during conduction and limited turn-off current or switching frequency during switching. High-frequency press-pack (HFPP) silicon carbide (SiC) field effect transistor (FET) modules that incorporate a substantial number of SiC FET dies in a single package can serve as a viable one-stop solution to address these issues. Due to the similarity of SiC FETs and Si IGBTs, existing PP IGBT modules can serve as a good design reference. However, the development of SiC FETs modules is much more challenging than IGBTs. For example, the size of SiC FET dies and pads is typically 50%-80% smaller than IGBT chips, making the press-contact to the source and gate pads using conventional technologies nearly impossible. Also, the high inductance and resistance of PP IGBT modules with stainless-steel disc springs (DSs) are tolerable for switching frequencies no higher than 1 kHz, but they are unacceptable for SiC FETs that can switch much faster, e.g., 10 times faster. One HFPP SiC MOSFET package attempt has been prototyped, in which fuzz buttons are used for die press-contact. However, fuzz buttons have low current ampacity, high stray inductance, and high resistance; they also lack SCFM due to insufficient contact stress.

Accordingly, there is a need for addressing these and other issues associated with the prior art technologies.

### SUMMARY

The systems and methods according to the present embodiments provide novel monolithic spring (MS) devices and power modules incorporating the same.

According to an embodiment, a spring device for use in a semiconductor device is provided that includes a body having a plurality of slits to allow the body to deflect along a first direction, and one or more legs at one or both ends of the body, wherein the plurality of slits are located in a plurality of planes perpendicular to the first direction and distributed along the first direction, and wherein the slits in a particular plane of the plurality of planes are interleaved with the slits in an adjacent plane of the plurality of planes.

In certain aspects, each plane of the plurality of planes has two slits among the plurality of slits located therein, and the two slits in a particular plane of the plurality of planes are perpendicular to each other. In certain aspects, the slits in a particular plane of the plurality of planes are rotated by 45 degrees with respect to the slits in an adjacent plane of the plurality of planes.

In certain aspects, the body is a rectangular cuboid or a cylinder extending along the first direction. In certain aspects, the body is made of Beryllium-Copper (BeCu) alloy, and the one or more legs are coated with silver.

In certain aspects, the plurality of planes are evenly distributed along the first direction. In certain aspects, the plurality of planes is denser towards the middle of the body.

In certain aspects, both ends of each slit among the plurality of slits in the body of the spring have rounded corners.

In certain aspects, the body has a through hole coincident with a centerline of the body, wherein the centerline is along the first direction, and wherein the through hole does not intersect with the one or more legs at the one end of the body.

In certain aspects, a footprint of each leg among the one or more legs is defined based on a pad area associated with a die, and wherein a particular leg is configured to contact a particular die by pressure provided by the spring.

In certain aspects, one end of the body comprises the one or more legs, and the other end of the body is a polished surface.

In certain aspects, one end of the body comprises a set of legs of the one or more legs, and the other end of the body comprises another set of legs of the one or more legs.

According to an embodiment, a power module is provided that includes a baseplate carrying one or more dies and a control circuit, the one or more dies each comprising one or more switch devices, and a spring device or assembly. The spring device or assembly includes a body having a plurality of slits to allow the body to deflect along a first direction, and one or more legs at one or both ends of the body, wherein the plurality of slits are located in a plurality of planes perpendicular to the first direction and distributed along the first direction, wherein the slits in a particular plane of the plurality of planes are interleaved with the slits in an adjacent plane of the plurality of planes, and wherein each leg of the one or more legs contacts one die of the one or more dies by pressure provided by the spring. The power module may also include a lid connected to one end of the body of the spring, wherein a current path is formed from the lid through the spring and the one or more dies to the baseplate, and the control circuit electrically connected to the switch devices comprised in the one or more dies.

In certain aspects, each plane of the plurality of planes has two slits among the plurality of slits located therein, and the two slits in a particular plane of the plurality of planes are perpendicular to each other.

In certain aspects, the slits in a particular plane of the plurality of planes are rotated by 45 degrees with respect to the slits in an adjacent plane of the plurality of planes.

In certain aspects, the body is a rectangular cuboid or a cylinder extending along the first direction.

In certain aspects, the plurality of planes are evenly distributed along the first direction.

In certain aspects, a footprint of each leg among the one or more legs is defined based on a pad area associated with a die, and a particular leg is configured to contact a particular die by pressure provided by the spring.

In certain aspects, one end of the body comprises the one or more legs, the other end of the body is a polished surface, and the lid is connected to the top surface of the body of the spring.

In certain aspects, one end of the body comprises a set of legs of the one or more legs, and the other end of the body comprises another set of legs of the one or more legs.

According to an embodiment, a method for fabricating a power module is provided.

The method may include providing a baseplate, the baseplate integrated with one or more dies and a control circuit, wherein the one or more dies each comprises one or more switch devices, and wherein the control circuit is electrically connected to the switch devices comprised in the one or more dies, and providing a spring, wherein the spring includes a body having a plurality of slits to allow the body to deflect along a first direction, and one or more legs at one end of the body, and a top surface at the other end of the body, wherein the plurality of slits are located in a plurality of planes perpendicular to the first direction and distributed along the first direction, and wherein the slits in a particular plane of the plurality of planes are interleaved with the slits in an adjacent plane of the plurality of planes. The method may also include placing each leg of the one or more legs on one die of the one or more dies to form a contact between the particular leg and the corresponding die, wherein the spring provides pressure to the contact between the particular leg and the corresponding die, and placing a lid on the top surface of the body of the spring, wherein a current path is formed from the lid through the spring and the one or more dies to the baseplate.

### BRIEF DESCRIPTION OF THE DRAWINGS

FIG. 1A is a diagram of an exemplary device employing individual DS assemblies.

FIG. 1B is a diagram of an exemplary device, according to one or more embodiments of the present disclosure.

FIG. 2A illustrates a three-dimensional (3D) rendering of a monolithic spring (MS), according to an embodiment of the present disclosure.

FIG. 2B is a top view of the monolithic spring (MS) as shown in FIG. 2A, according to an embodiment of the present disclosure.

FIG. 2C is a bottom view of the MS as shown in FIG. 2A, according to an embodiment of the present disclosure.

FIG. 2D is a side view of the MS as shown in FIG. 2A, according to an embodiment of the present disclosure.

FIGS. 3A-3C illustrate finite element analysis (FEA) results of an exemplary MS in isometric view, side view, and bottom view, respectively, according to one embodiment of the present disclosure.

FIG. 3D shows an exemplary bidirectional MS structure, according to an embodiment of the present disclosure.

FIGS. 4A-4B exhibit two variable-scanning cases, according to embodiments of the present disclosure.

FIG. 5A illustrates a 3D rendering of a bidirectional MS, according to an embodiment of the present disclosure.

FIG. 5B is a side view of the bidirectional MS as shown in FIG. 5B.

### DESCRIPTION

To address the press-contact and parasitics challenges for high-frequency press-pack (HFPP) silicon carbide (SiC) field-effect transistor (FET) modules, the present disclosure provides novel monolithic spring (MS) devices. In certain embodiments, the MS may be made of a Beryllium-Copper (BeCu) block or other material with a high yield strength. In one particular embodiment, an MS has four legs at the bottom to be sintered to four small SiC FET dies. In one embodiment, multiple layers of interleaved slits are formed, e.g., laser-cut, horizontally to provide the space for deflection in the vertical direction and a linear spring constant. The slits also create a greater surface area for high-frequency current conduction and hence lead to lower high-frequency resistance. Because the MS is not made of discs or spiral wires, it also features trivial stray inductance. Advantages of the embodiments herein include an innovative MS structure and a MS design and optimization approach to meet a specified deflection distance, spring constant, and stress uniformity while minimizing parasitics.

The earliest generations of press-pack (PP) insulated gate bipolar transistor (IGBT) modules were of a rigid-type that exhibited stress non-uniformity issues on chips when many IGBT chips are incorporated. To mitigate these issues, one solution is to use individual disc spring (DS) assemblies to provide contact stress on each IGBT chip.

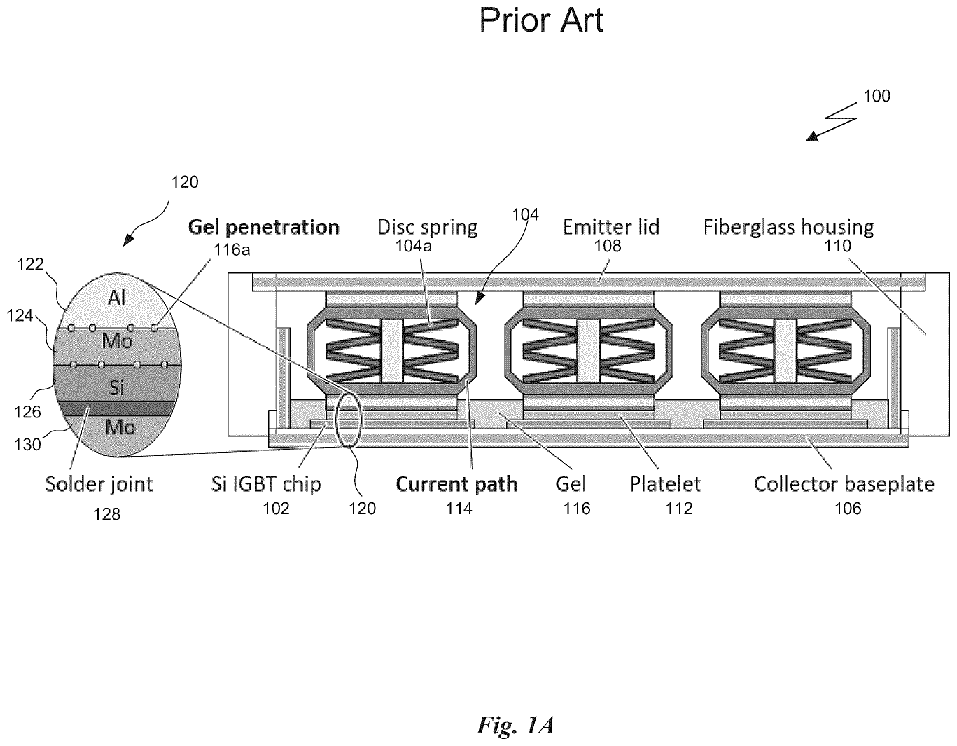

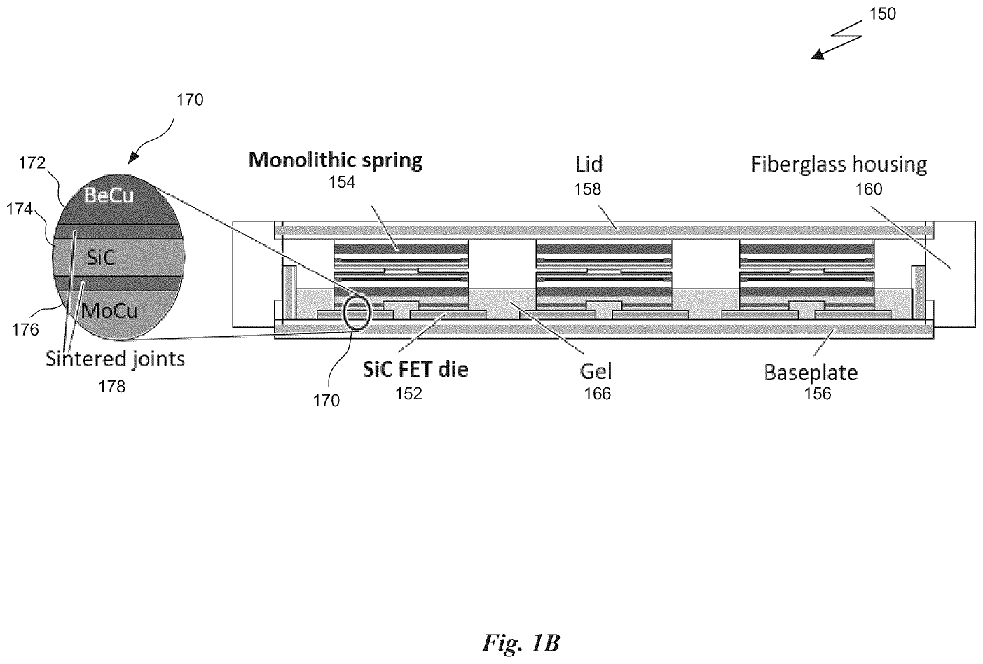

FIG. 1A is a diagram of an exemplary device 100 employing individual DS assemblies. The device 100 is a compliant-type PP IGBT (e.g., the product named “StakPak” from ABB Semiconductors (now Hitachi Energy)).

As shown in FIG. 1A, the device 100 is enclosed in a fiberglass housing 110. Within the device 100, a plurality of silicon (Si) IGBT chips 102 are positioned on a collector baseplate 106, where the collector pads of the IGBTs on the chips 102 are electrically coupled to the collector baseplate 106. The baseplate 106 is arranged on one side (e.g., bottom) of the fiberglass housing 110, while an emitter lid 108 is disposed on the opposite side (e.g., top) of the housing 110. The emitter pads of the IGBTs on the chips 102 are electrically coupled to the emitter lid 108. A plurality of DS assemblies 104 are disposed between the collector baseplate 106 and the emitter lid 108, with the DS assemblies 104 connected between corresponding IGBT chips 102 and the emitter lid 108. Each DS assembly 104 includes a stainless-steel DS 104a at the center and additional copper current paths 114 patched on two sides. Current may flow through the DS 104a and/or the copper current paths 114. An region 120 of the device 100 is zoomed out, revealing five layers. From top to bottom, the five layers are as follows: an aluminum (Al) layer 122, a first Molybdenum (Mo) layer 124, a silicon layer 126, a solder joint layer 128, and a second Mo layer 130. These layers represent a DS assembly 104, a platelet 112, a IGBT chip 102, a solder joint 128, and the collector baseplate 106, respectively. The plurality of Si IGBT chips 102 are affixed on the collector baseplate 106 via the corresponding solder joints 128. The plurality of DS assemblies 104 contact the emitter pads of the IGBT chips 102. A gel layer 116 is applied to the collector baseplate 106, which may cause gel penetration (e.g., 116a) at the interfaces between the Al layer 122 and the first Mo layer 124, and between the first Mo layer 124 and the silicon layer 126.

The design as shown in FIG. 1A features high flexibility and easy handling. However, such a DS-based design has several drawbacks. For example, a single stainless-steel disc offers a tiny deflection range, so each DS assembly consists of many series-stacked discs to meet a required total deflection, leading to an inevitably high module thickness and weight. Second, a stainless steel DS assembly cannot conduct current well, so additional copper current paths are patched at two sides. This design introduces two extra high-resistance dry-contact interfaces and does not leverage the large PP cross-section for vertical current conduction at all. Third, the thermal conductivity through the DS assemblies is reported to be only 30% of that through the baseplate due to the air space, leading to ineffective double-sided cooling. Furthermore, the internal dry-contact interfaces are reported to have a gel-penetration issue in the long term.

FIG. 1B is a diagram of an exemplary device 150, according to one or more embodiments of the present disclosure. The device 150 is a HFPP switch cell, which is enclosed in a fiberglass housing 160. A baseplate 156 and a lid 158 are positioned on opposite sides (e.g., bottom and top, respectively) within the housing 160. A plurality of SiC FET dies 152 are positioned on the baseplate 156. A plurality of monolithic springs (MSs) 154 are disposed between the baseplate 156 and the lid 158, with the MSs 154 connected between corresponding SiC FET dies 152 and the lid 158. As shown in FIG. 1B, each MS 154 contacts a group of SiC FET dies 152 (e.g., through legs). An region 170 of the device 150 is zoomed out, revealing five layers. From top to bottom, the five layers are as follows: BeCu layer 172, a first sintered joint layer 178, a SiC layer 174, a second sintered joint layer 178, and a Molybdenum-Copper (MoCu) layer 176. These layers represent a MS 154, a sintered joint 178 between the MS 154 and a SiC FET die 152, the respective SiC FET die 152, a sintered joint 178 between the respective SiC FET die 152 and the baseplate 156, and the baseplate 156, respectively. The plurality of SiC FET dies 152 are affixed to the baseplate 156 via a plurality of sintered joints 178 in the second sintered joint layer, and the MSs 154 are sintered to the SiC FET dies 152 (e.g., to the source pads of the SiC FET dies 152) via a plurality of sintered joints 178 in the first sintered joint layer. A gel layer 166 is applied to the baseplate 156. A current path is formed from the lid 158 through the MS 154 and the one or more dies 152 to the baseplate 156.

It will be noted that the choice of materials for the components discussed in the present disclosure is merely for illustrative purposes. Other suitable materials may be used, and a different number of layers/components may be employed in a suitable product for various usage scenarios.

In an embodiment, the baseplate 156 may further include a control circuit to control the operation of the switch devices (e.g., FETs) in the SiC FET dies 152. For example, the control circuit is electrically connected to the switch devices comprised in the one or more dies 152.

Comparing to the device 100 as shown in FIG. 1A, the device 150 as shown in FIG. 1B replaces the DS assemblies (e.g., 104) with MS assemblies (e.g., 154) according to embodiments herein.

In an embodiment, the MS 154 is made of a BeCu block with interleaved laser-cut slits, multiple (e.g., four) coated (e.g., silver-coated) or uncoated legs, and a polished top surface, which features significant benefits. For example, the slits yield a required spring constant with a proper geometric design and reduce high-frequency resistance without increasing the stray inductance. Second, the optionally coated legs can be sized to fit different SiC FET die areas and directly sintered to the source pads. Thirdly, an optionally polished top surface reduces the dry-contact electrical and thermal resistance under fixed stress and hence reduces the required stress to achieve effective conductivities (e.g., >70% of the bottom). Furthermore, the directly bonded MS can more uniformly distribute the junction temperature of the multiple dies and yield large adjacent thermal capacitance to smooth the junction temperature variation under transient power losses (e.g., short-circuit fault).

In an embodiment, the sintered joints are made of silver sinter paste, where silver coating may be applied to one or more legs of the MS 154 for silver sintering. In another embodiment, the sintered joints are made of copper sinter paste, where the one or more legs of the MS 154 may not be coated for the sintering process. However, it should be noted that alternative materials and/or procedures may be employed for the sintering process.

In an embodiment, the MS assembly is bidirectional, with both sides designed with legs that contact switch devices (e.g., SiC FETs on the SiC FET dies 152).

### MS Structure and Modelling

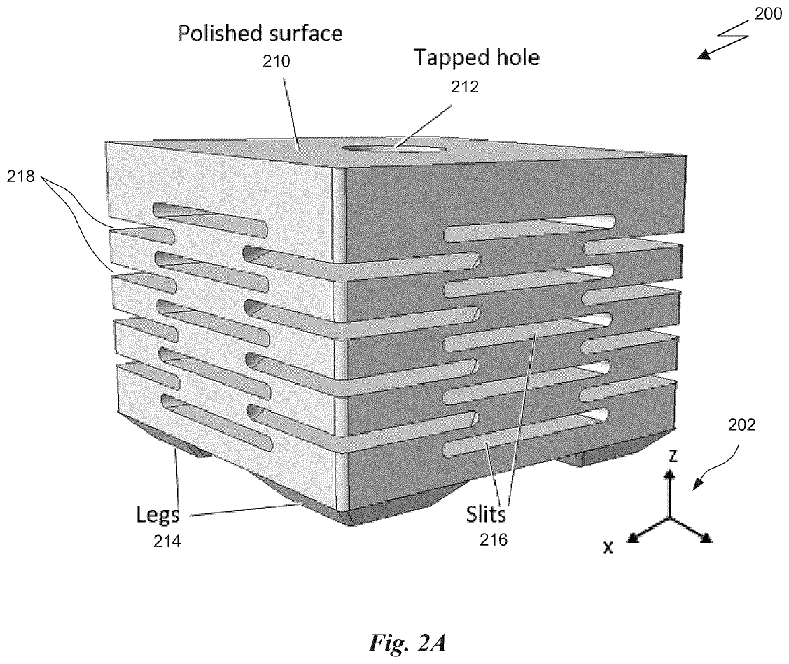

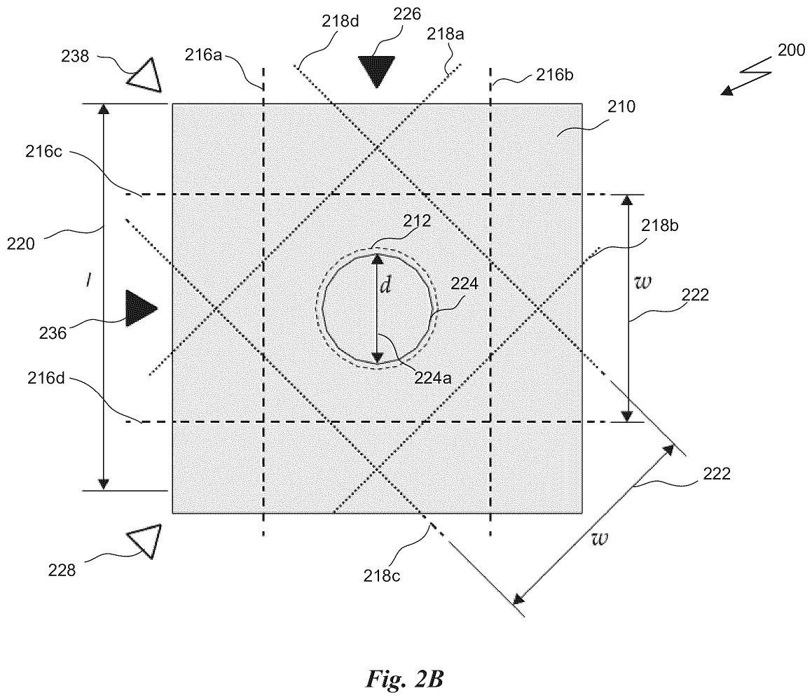

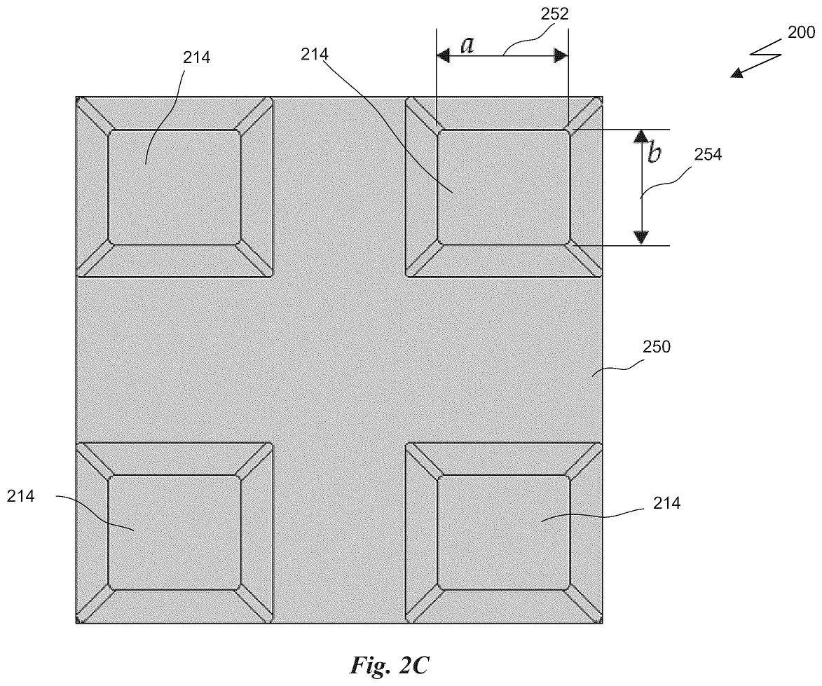

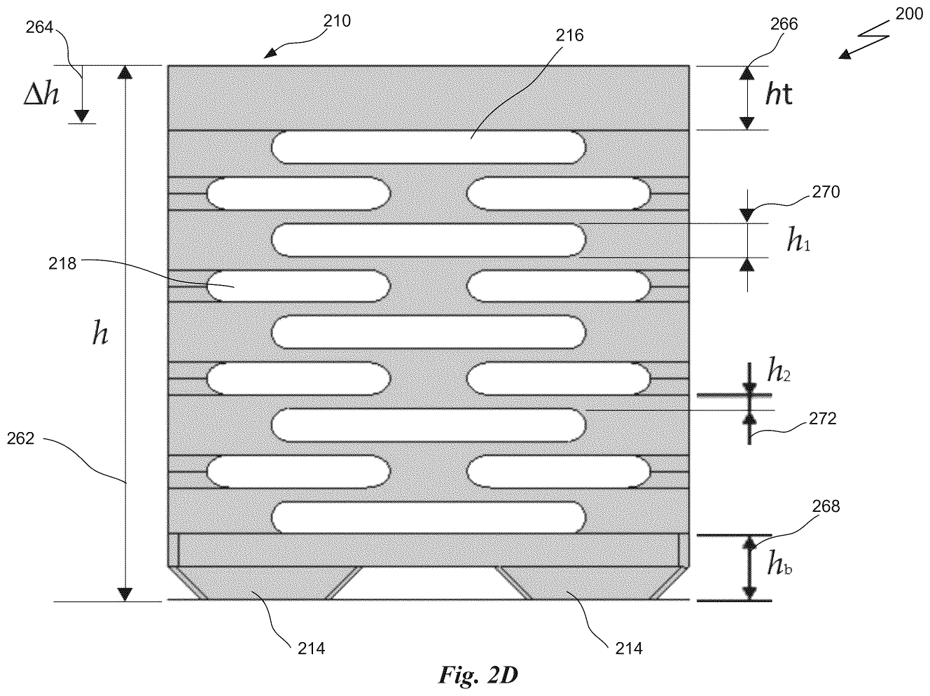

FIG. 2A illustrates a three-dimensional (3D) rendering of a monolithic spring (MS) 200, according to an embodiment of the present disclosure. The MS 200 is designed with a spring that deflects along z-axis of the reference coordinate system 202. As shown in FIG. 2A, the MS 200 is shaped like a block with a top surface 210 and a base designed with four legs 214. The MS 200 includes multiple evenly distributed horizontal layers (parallel to the zy plane) of airgap slits 216 and 218. Each horizontal layer may correspond to a plane (e.g., parallel to the zy plane). For example, the slits 216 penetrate through the block's two opposite side faces, while the slits 218 penetrate through the block diagonally. The four legs 214 at the base are utilized for die attachment. In this example, the top surface 210 is a polished surface, and a tapped hole 212 is designed on the top surface of the block.

In some embodiments, the distribution or density of horizontal layers may vary, e.g., being denser in the middle. In other words, it may be designed with denser slits in the middle than at the top and/or bottom ends of the MS 200. The number of legs may vary, depending on the number of dies for attachment. For example, the number of legs may range from 2 to 16 or more.

In an embodiment, for each layer, two orthogonal planes are used to cut the slits through the MS body. FIG. 2B is a top view of the MS 200 as shown in FIG. 2A, according to an embodiment of the present disclosure. The DS width 220 of the MS 200 is denoted as l, slit width 222 is denoted as w, and the diameter 224a of a through-hold 224 is denoted as d. The through-hole 224 is not through the base layer, which may be coaxial with the tapped hole 212 (dashed circle, for mounting).

In this example, two orthogonal planes corresponding to solid arrows 226 and 236 are used to cut the slits 216 through the MS body 200. For example, a subset of slits 216 corresponding to the pair of dashed lines 216a and 216b is orthogonal to another subset of slits 216 corresponding to the pair of dashed lines 216c and 216d. Additionally, two orthogonal planes corresponding to hollow arrows 228 and 238 are used to cut the slits 218 through the MS body 200. For example, a subset of slits 218 corresponding to the pair of dashed lines 218a and 218b is orthogonal to another subset of slits 216 corresponding to the pair of dashed lines 218c and 218d. In some embodiments, the arrows 226, 236, 228, and 238 may denote laser-cutting directions.

The orthogonal planes on every other layer may interleaved by rotating (e.g., 45°, 90°, etc.) around the z-axis, and hence the slits (e.g., the slits 218) on the corner edges may be created.

FIG. 2C is a bottom view of the MS 200 as shown in FIG. 2A, according to an embodiment of the present disclosure. As show in FIG. 2C, four legs 214 may be arranged on the four corners of the base 250 of the MS 200. The four legs 214 of the base 250 may be designed with raised shapes, where the raised portions may include a flat surface defined by footprint parameters 252 and 254, denoted as a and b, respectively.

FIG. 2D is a side view of the MS 200 as shown in FIG. 2A, according to an embodiment of the present disclosure. From this view, the following parameters may be defined. The height 262 of the MS 200 is denoted as h. The deflection 264 of the MS 200 relative to the total height h is denoted as Δh. In this example, the slits (e.g., 216 and 218) are designed with a uniform distribution/density. The slit height is denoted as h₁ and the vertical distance between adjacent slits is denoted as h₂. A top layer height 266, denoted as hₜ, represents the vertical distance between the top surface 210 of the MS 200 and the upper surface of the topmost slit (e.g., a slit 216 or 218). A bottom layer height 268, denoted as hp, represents the vertical distance between the lower surface of the legs 214 of the MS 200 and the lower surface of the bottommost slit (e.g., a slit 216 or 218).

In an embodiment, the cubical MS's design variables may include the following, with reference to FIGS. 2A-2D: (1) the width l of the MS body 200 (square from top view in FIG. 2B), determined by the FET die size and distance; (2) the slit width w (optionally with two corners rounded, to reduce stresses and computational costs of FEA simulations); 3) the slit height h₁, the vertical distance h₂ between slits, and the total slit layer number n; 4) the top layer (optionally with a tapped hole for mounting to a lid, as shown in FIG. 2B) height hₜ and bottom layer (with legs, e.g., four legs, but not holes) height hp; 5) the cylindrical hole diameter d through all inner layers; 6) the footprint dimensions a and b (as shown in FIG. 2C); and 7) a clamping force F.

In an embodiment, the MS may have a cylindrical shape. In a study, a cylindrical MS was analyzed and compared to the cubical design. The cubical turned out to be superior. Other shapes may be used such as triangular or octagonal cross sections perpendicular to the axis or centerline.

The mechanical and electrical performance of an MS may be correlated with one or more of the design variables discussed herein. In an embodiment, certain variables may be predetermined. For example, in an exemplary usage case, the following values are adopted for certain variables: l=16 mm, h_{c}=h)=3 mm, a=3.92 mm, b=3.34 mm, and F=700 N. Other variables may be tuned to adjust the mechanical and electrical performance of the MS based on the corresponding correlations.

In an embodiment, an internal through-hole at the center is included (e.g., as shown in FIG. 2B), for several reasons. First, the through-hole (e.g., 224) does not intersect with the legs 214, and no stress is needed in the center. Second, for the same values of w, h₁, and h₂, the through-hole 224 can lower the body stress and increase the deflection Δh. Third, the through-hole 224 can reduce the mass m without increasing resistance and stray inductance significantly. For a spring design, an important constraint is that the spring must operate within the material's elastic region without entering the plastic region; otherwise, permanent, irreversible, or plastic deformation occurs. To assure that, the maximum body stress (σbody, max) must be lower than the material's yield strength (σy) with margin. In an embodiment, BeCu alloy is selected for its high tensile strength of σy=1206 MPa. Since BeCu contains more than 97% copper (Cu %), its electrical and thermal characteristics are nearly the same as Cu. Other useful materials for the MS body be used as would be apparent to one skilled in the art. Another constraint is that Δh>1.5 mm; otherwise, the manufacturing tolerance may result in an inaccurate clamping force.

In certain aspects, the lid and/or baseplate (e.g., as shown in FIG. 1B) may include Cu-Diamond (CuDmd). Other useful materials for the baseplate and lid may be used as would be apparent to one skilled in the art.

### Simulation and Fabrication

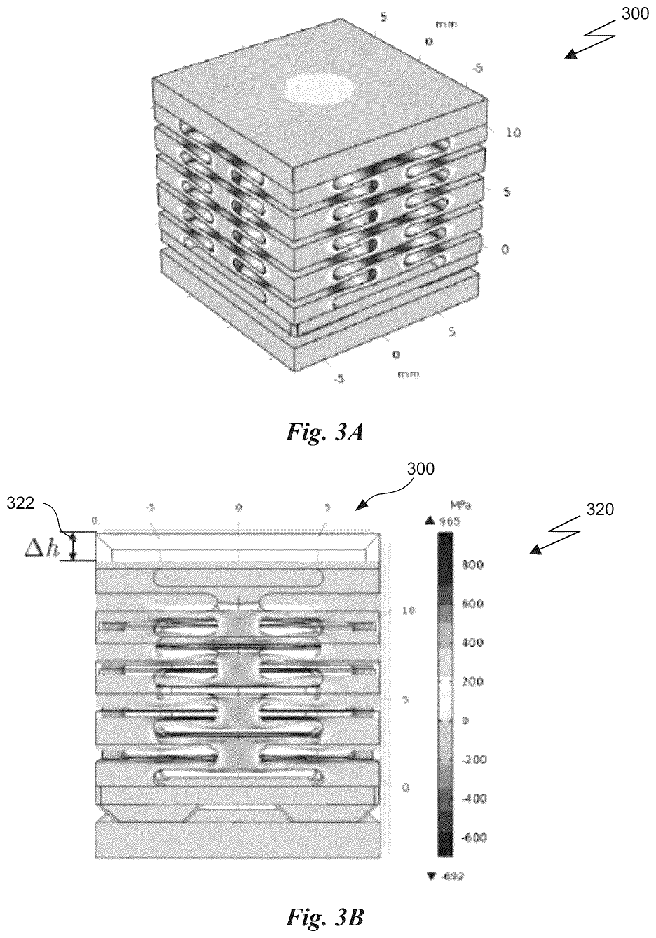

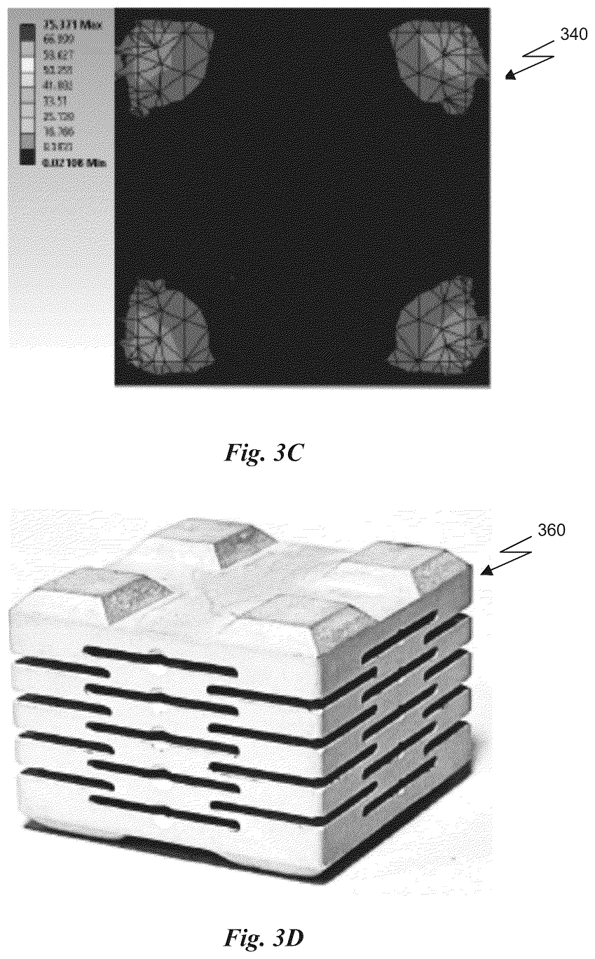

Many FEA simulation cases have been conducted to optimize the MS design. In one example, the predetermined parameters are: (=16 mm, h_{c}=h_{b}=3 mm, a=3.92 mm, b=3.34 mm, and F=700 N; the design variables are w, h₁, h₂, d, and n; the constraints are σbody, max<0.9σy, BeCu, Δh>1.5 mm, and σleg, avg<50 MPa, where σleg, avg represents the leg stress; and the objective functions are to minimize total height (h), total mass (m), direct current (dc) resistance (R_{dc}), alternating current (ac) resistance (R_{ac}), and stray inductance (Lₛ). The FEA simulations are performed in COMSOL Structural Mechanics/ANSYS Mechanical and Electronics (Q3D), and data process is done in MATLAB. Every case generates FEA simulation results such as in FIGS. 3A-3C and exports associated data to MATLAB.

FIGS. 3A-3C illustrate FEA results of an exemplary MS 300 in isometric view, side view 320, and bottom view 340, respectively, according to one embodiment of the present disclosure. It is noted that, in FIG. 3B, the positive values correspond to tensile stresses, while the negative are compressive stresses.

These FEA simulations may be conducted on other types of MS structures. FIG. 3D shows an exemplary bidirectional MS structure 360, according to an embodiment of the present disclosure. The MS structure 360 may incorporate a similar slit and/or leg design as the MS 200 depicted in FIGS. 2A-2D. In contrast, the MS structure 360 is designed with legs on both ends, such as at the top and bottom.

The FEA results in FIGS. 3A-3C are from a valid case with predetermined l=16 mm, ht=hb=3 mm, a=3.92 mm, b=3.34 mm, and F=700 N. The design variables w=7.64 mm, h1=1.0 mm, h2=0.42 mm, d=8 mm, and n=9. The constraints σbody, max=965 MPa, Δh=1.51 mm, and σbody, avg=18.4 MPa are satisfied. The objective functions are h=12.4 mm, m=35.0 g, Rdc=106 μΩ, Rac=122 μΩ@20 kHz, and Ls=3.75 nH. This case verifies that the MS is remarkably suited for high-frequency, high-current applications owing to the low profile, low ac resistance, and low stray inductance.

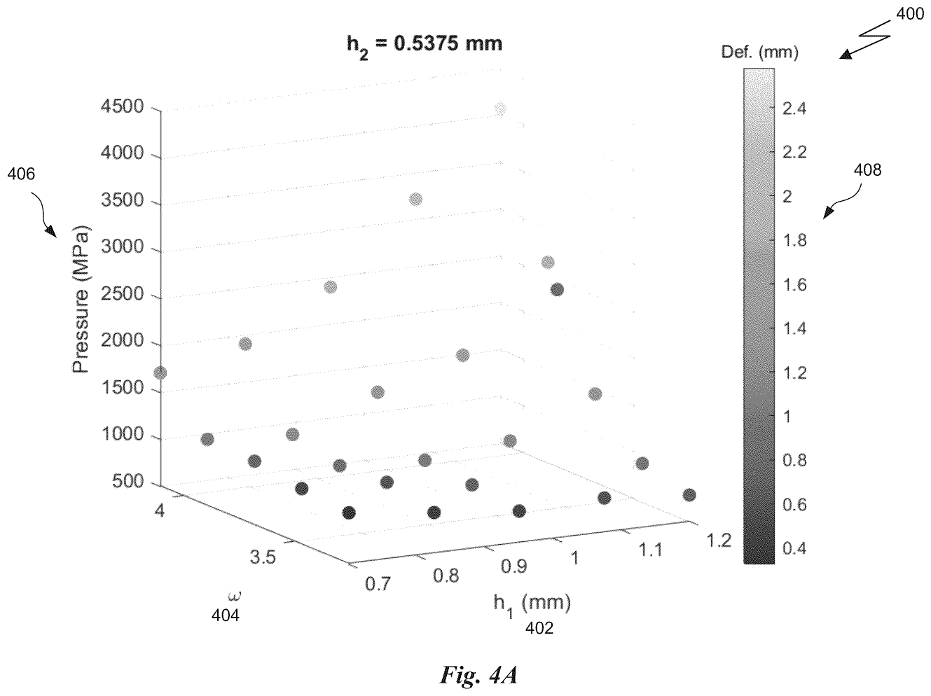

FIG. 4A and FIG. 4B exhibit two variable-scanning cases (400, 420), according to embodiments of the present disclosure. In both cases, variables h1 (402) and w (404) are scanned, with h2=0.5375 set in case 400 and h2=0.35 set in case 420, respectively. The vertical axis 406 represents the maximum body stress (σbody, max) in megapascals (MPa), while the scale bar 408 indicates the range of the deflection (Δh) in millimeters. Valid design cases can be found below the plane of σbody, max=1085 MPa, with the color of dots satisfying Δh>1.5 mm.

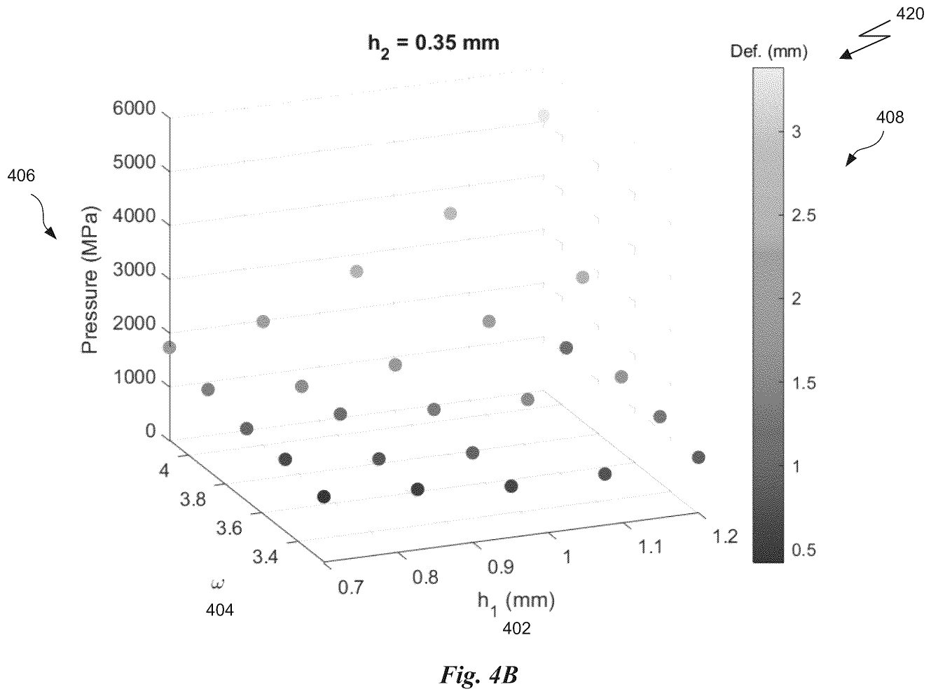

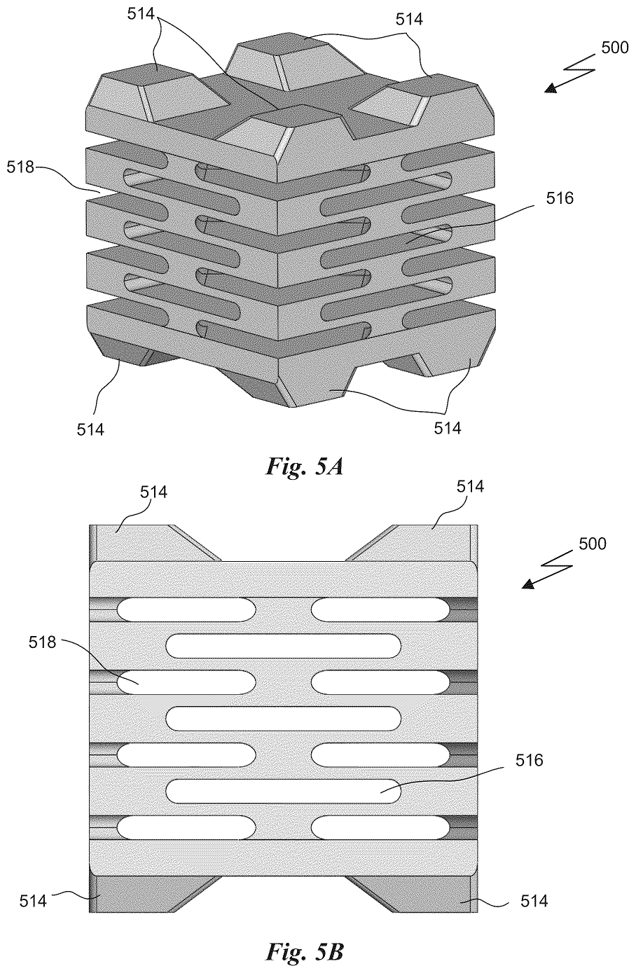

FIG. 5A illustrates a 3D rendering of a bidirectional MS 500, according to an embodiment of the present disclosure. FIG. 5B is a side view of the bidirectional MS 500 as shown in FIG. 5B. As shown in FIGS. 5A and 5B, the MS 500 is designed with legs 514 on both ends, and interleaved slits 516 and 518 similar to the slits 216 and 218 as shown in FIGS. 2A and 2D.

As the foregoing illustrates, the present disclosure provides exemplary embodiments of a spring for use in a semiconductor device. The spring is a monolithic spring (MS), which may implement any of the design disclosed herein.

In an embodiment, the spring comprises a body having a plurality of slits to allow the body to deflect along a first direction, and one or more legs at one or both ends of the body.

For example, the body of the MS 200 as shown in FIG. 2A has a plurality of slits distributed along z-axis. The MS 200 in FIGS. 2A-2D has four legs on one end of the body, while the MS 500 in FIGS. 5A-5B has four legs on both sides of the body. However, different numbers and/or arrangement of legs may be designed on either or both sides of the body.

As demonstrated with reference to FIG. 2B, the plurality of slits are located in a plurality of planes perpendicular to the first direction (e.g., z-axis) and distributed along the first direction. The slits in a particular plane of the plurality of planes are interleaved with the slits in an adjacent plane of the plurality of planes.

In an embodiment, each plane of the plurality of planes has two slits among the plurality of slits located therein, and the two slits in a particular plane of the plurality of planes are perpendicular to each other.

In an embodiment, the slits in a particular plane of the plurality of planes are rotated by 45 degrees with respect to the slits in an adjacent plane of the plurality of planes.

In an embodiment, the body is a rectangular cuboid or a cylinder extending along the first direction.

In an embodiment, the body is made of Beryllium-Copper (BcCu) alloy. The one or more legs may be coated with silver. Alternatively, one or more legs may not be coated.

In an embodiment, the plurality of planes are evenly distributed along the first direction.

In an embodiment, both ends of each slit among the plurality of slits in the body of the spring have rounded corners. The rounded corners may be made by a drilling tool in the fabrication process.

In an embodiment, the body has a through hole coincident with a centerline of the body. The centerline is along the first direction, and the through hole does not intersect with the one or more legs at the one end of the body.

In an embodiment, a footprint of each leg among the one or more legs is defined based on a pad area associated with a die. A particular leg is configured to contact a particular die by pressure provided by the spring.

In some embodiments, the present disclosure provides a power module. The power module comprises a baseplate carrying one or more dies, a spring provided in the present disclosure, and a lid connected to one end of the spring. The one or more dies each comprises one or more switch devices (e.g., FETs). A current path is formed from the lid through the spring and the one or more dies to the baseplate.

In an embodiment, the spring comprises a body having a plurality of slits to allow the body to deflect along a first direction, one or more legs at one end of the body, and a top surface at the other end of the body. In another embodiment, the spring comprises a body having a plurality of slits to allow the body to deflect along a first direction, and one or more legs at both ends of the body.

In an embodiment, the plurality of slits are located in a plurality of planes perpendicular to the first direction and distributed along the first direction. The slits in a particular plane of the plurality of planes are interleaved with the slits in an adjacent plane of the plurality of planes. Each leg of the one or more legs contacts one die of the one or more dies by pressure provided by the spring.

An exemplary power modules may be fabricated by performing some or all of the following steps in any suitable order.

In a first step, a baseplate is provided, which is integrated with one or more dies and a control circuit. The one or more dies each comprises one or more switch devices. The control circuit is electrically connected to the switch devices comprised in the one or more dies.

In a second step, a spring is provided. The spring may be any of the springs disclosed herein. In one embodiment, the spring comprises a body having a plurality of slits to allow the body to deflect along a first direction, one or more legs at one end of the body, and a top surface at the other end of the body. In another embodiment, the spring comprises a body having a plurality of slits to allow the body to deflect along a first direction, and one or more legs at both ends of the body. The plurality of slits are located in a plurality of planes perpendicular to the first direction and distributed along the first direction. The slits in a particular plane of the plurality of planes are interleaved with the slits in an adjacent plane of the plurality of planes.

In a third step, each leg of the one or more legs is placed on one die of the one or more dies to form a contact between the particular leg and the corresponding die. The spring provides pressure to the contact between the particular leg and the corresponding die.

In a fourth step, a lid is placed on one end (e.g., the top surface) of the body of the spring. A current path is formed from the lid through the spring and the one or more dies to the baseplate.

Examples of HFPP designs utilizing monolithic springs (MSs) according to embodiments may be found in provisional application No. 63/496,779, titled “HIGH-FREQUENCY PRESS-PACK SIC FIELD EFFECT TRANSISTOR (FET) MODULES”, filed on Apr. 18, 2023, which is incorporated by reference in its entirety.

U.S. patent application Ser. No. 18/175,980, filed Feb. 28, 2023, titled POWER MODULES FOR CIRCUIT PROTECTION, and U.S. Provisional Patent Application No. 63/315,195, filed Mar. 1, 2022, titled PASSIVELY COOLED ULTRA-EFFICIENT AND RELIABLE INTELLIGENT POWER MODULE FOR MVDC SOLID-STATE CIRCUIT BREAKERS, both disclose additional aspects of power modules, including switch cell components and switch cell modules, useful in embodiments herein, and are both incorporated by reference herein for all purposes.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the disclosed subject matter (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or example language (e.g., “such as”) provided herein, is intended merely to better illuminate the disclosed subject matter and does not pose a limitation on the scope of the invention unless otherwise claimed. No language in the specification should be construed as indicating any non-claimed element as essential to the practice of the invention.

Certain embodiments are described herein. Variations of those embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

What is claimed is:

1. A spring for use in a semiconductor device, the spring comprising:
a body having a plurality of slits to allow the body to deflect along a first direction; and
one or more legs at one or both ends of the body,
wherein the plurality of slits are located in a plurality of planes perpendicular to the first direction and distributed along the first direction, and
wherein the slits in a particular plane of the plurality of planes are interleaved with the slits in an adjacent plane of the plurality of planes.

2. The spring according to claim 1, wherein each plane of the plurality of planes has two slits among the plurality of slits located therein, and the two slits in a particular plane of the plurality of planes are perpendicular to each other.

3. The spring according to claim 2, wherein the slits in a particular plane of the plurality of planes are rotated by 45 degrees with respect to the slits in an adjacent plane of the plurality of planes.

4. The spring according to claim 1, wherein the body is a rectangular cuboid or a cylinder extending along the first direction.

5. The spring according to claim 1, wherein the body is made of Beryllium-Copper (BeCu) alloy, and the one or more legs are coated with silver.

6. The spring according to claim 1, wherein the plurality of planes are evenly distributed along the first direction.

7. The spring according to claim 1, wherein both ends of each slit among the plurality of slits in the body of the spring have rounded corners.

8. The spring according to claim 1, wherein the body has a through hole coincident with a centerline of the body, wherein the centerline is along the first direction, and wherein the through hole does not intersect with the one or more legs at the one end of the body.

9. The spring according to claim 1, wherein a footprint of each leg among the one or more legs is defined based on a pad area associated with a die, and wherein a particular leg is configured to contact a particular die by pressure provided by the spring.

10. The spring according to claim 1, wherein one end of the body comprises the one or more legs, and wherein the other end of the body is a polished surface.

11. The spring according to claim 1, wherein one end of the body comprises a set of legs of the one or more legs, and wherein the other end of the body comprises another set of legs of the one or more legs.

12. A power module, comprising:
a baseplate carrying one or more dies and a control circuit;
the one or more dies each comprising one or more switch devices;
a spring comprising:
a body having a plurality of slits to allow the body to deflect along a first direction; and
one or more legs at one or both ends of the body;
wherein the plurality of slits are located in a plurality of planes perpendicular to the first direction and distributed along the first direction,
wherein the slits in a particular plane of the plurality of planes are interleaved with the slits in an adjacent plane of the plurality of planes, and
wherein each leg of the one or more legs contacts one die of the one or more dies by pressure provided by the spring;
a lid connected to one end of the body of the spring, wherein a current path is formed from the lid through the spring and the one or more dies to the baseplate; and
the control circuit electrically connected to the switch devices comprised in the one or more dies.

13. The power module according to claim 12, wherein each plane of the plurality of planes has two slits among the plurality of slits located therein, and the two slits in a particular plane of the plurality of planes are perpendicular to each other.

14. The power module according to claim 13, wherein the slits in a particular plane of the plurality of planes are rotated by 45 degrees with respect to the slits in an adjacent plane of the plurality of planes.

15. The power module according to claim 12, wherein the body is a rectangular cuboid or a cylinder extending along the first direction.

16. The power module according to claim 12, wherein the plurality of planes are evenly distributed along the first direction.

17. The power module according to claim 12, wherein a footprint of each leg among the one or more legs is defined based on a pad area associated with a die, and wherein a particular leg is configured to contact a particular die by pressure provided by the spring.

18. The power module according to claim 12, wherein one end of the body comprises the one or more legs, wherein the other end of the body is a polished surface, and wherein the lid is connected to the top surface of the body of the spring.

19. The power module according to claim 12, wherein one end of the body comprises a set of legs of the one or more legs, and wherein the other end of the body comprises another set of legs of the one or more legs.

20. A method for fabricating a power module, comprising:
providing a baseplate, the baseplate integrated with one or more dies and a control circuit, wherein the one or more dies each comprises one or more switch devices, and wherein the control circuit is electrically connected to the switch devices comprised in the one or more dies;
providing a spring, wherein the spring comprises:
a body having a plurality of slits to allow the body to deflect along a first direction; and
one or more legs at one end of the body; and
a top surface at the other end of the body,
wherein the plurality of slits are located in a plurality of planes perpendicular to the first direction and distributed along the first direction, and
wherein the slits in a particular plane of the plurality of planes are interleaved with the slits in an adjacent plane of the plurality of planes, and
placing each leg of the one or more legs on one die of the one or more dies to form a contact between the particular leg and the corresponding die, wherein the spring provides pressure to the contact between the particular leg and the corresponding die; and
placing a lid on the top surface of the body of the spring, wherein a current path is formed from the lid through the spring and the one or more dies to the baseplate.
